(19) United States
(12) Patent Application Publication
(10) Pub. No.: US 2022/0059994 A1
(43) Pub. Date: Feb. 24, 2022

(54) SEMICONDUCTOR APPARATUS AND METHOD FOR MANUFACTURING SEMICONDUCTOR APPARATUS

(71) Applicant: SONY GROUP CORPORATION, TOKYO (JP)

(72) Inventor: YASUHIRO KADOWAKI, TOKYO (JP)

(21) Appl. No.: 17/299,457

(22) PCT Filed: Nov. 21, 2019
(86) PCT No.: PCT/JP2019/045536

§ 371 Date: Jun. 3, 2021

(30) Foreign Application Priority Data
Dec. 13, 2018 (JP) 2018-233905

(51) Int. Cl. H01S 5/22; H01S 5/343

(52) U.S. Cl. CPC H01S 5/2216; H01S 5/343

(57) ABSTRACT

Degradation of laser characteristics and increase in variations in characteristics are reduced. A semiconductor apparatus (100) includes a semiconductor chip including a semiconductor substrate (1) including a group-III nitride semiconductor and a laminate structure (2) located on a first surface (1a) of the semiconductor substrate (1), and on at least one of side surfaces of the semiconductor chip orthogonal to the first surface (1a), plural groove-like machining traces (105) are provided at a pitch of 2 μm (micrometers) or more but 30 μm or less in a direction parallel to a second surface (1b) of the semiconductor substrate (1) opposite to the first surface (1a) of the semiconductor substrate (1), the groove-like machining traces extending from the second surface (1b) to a third surface (1a) of the laminate structure (2) opposite to a surface of the laminate structure (2) contacting the first surface (1a).

### TECHNICAL FIELD

The present disclosure relates to a semiconductor apparatus and a method for manufacturing the semiconductor apparatus.

### BACKGROUND ART

Semiconductor laser elements are now used in various technical fields, and have become essential optical devices particularly in the field of video display apparatuses such as televisions and projectors, for example. Such applications need semiconductor laser elements respectively outputting red light, green light, and blue light constituting three primary colors of light. Semiconductor laser elements for red and blue light have already been put to practical use, and recently, semiconductor laser elements for green light (wavelength of approximately 500 to 560 nm) have also been actively developed.

As a semiconductor laser element that can output green laser light, a semiconductor laser element for which a hexagonal group-III nitride semiconductor is used has been developed. In the semiconductor laser element for which the hexagonal group-III nitride semiconductor is used, an end surface of the semiconductor laser element that is orthogonal to a propagation direction (waveguide direction) of laser light is used as a reflection surface (hereinafter referred to as a resonator end surface).

In a method for manufacturing a semiconductor laser element with such a structure, first, plural laser structures are formed on a semi-polar surface of a semiconductor substrate including a hexagonal group-III nitride semiconductor. Then, in the semi-polar surface on which the laser structures have been formed, a scribe groove extending in a predetermined direction is formed using a laser scriber. Subsequently, a blade is pressed against a surface of the semiconductor substrate opposite to the semi-polar surface along the scribe groove, to cleave and singulate the semiconductor substrate into semiconductor laser elements. End surfaces formed by the cleavage in that case are used as resonator end surfaces.

### CITATION LIST

### Patent Literature

[PTL 1]

Japanese Patent Laid-open No. 2015-159193

### SUMMARY

### Technical Problems

However, in the semiconductor laser element for which the hexagonal group-III nitride semiconductor is used, in a case where resonator end surfaces are formed by cleaving a semiconductor substrate with a crystal grown on a semi-polar surface as in the related art, scribing is significantly affected by a {0001} plane corresponding to a substrate crystal surface near the cleavage position under scribe conditions equivalent to known scribe conditions for the {0001} plane. Thus, it is difficult to form the cleavage surface perpendicularly to the semi-polar surface. In a case where the cleavage surface is tilted relative to the semi-polar surface, such problems as degraded characteristics of the semiconductor laser element, increased variations in characteristics, and the like may occur.

Thus, the present disclosure proposes a semiconductor apparatus and a method for manufacturing the semiconductor apparatus, the semiconductor apparatus and the method being capable of reducing the degradation of the laser characteristics and the increase in variations in characteristics.

### Solution to Problems

To achieve the object, a semiconductor apparatus of an aspect according to the present disclosure includes a semiconductor chip including a semiconductor substrate including a group-III nitride semiconductor and a laminate structure located on a first surface of the semiconductor substrate, and on at least one of side surfaces of the semiconductor chip orthogonal to the first surface, plural groove-like machining traces are provided at a pitch of 2 μm (micrometers) or more but 30 μm or less in a direction parallel to a second surface of the semiconductor substrate opposite to the first surface of the semiconductor substrate, the groove-like machining traces extending from the second surface to a third surface of the laminate structure opposite to a surface of the laminate structure contacting the first surface.

### BRIEF DESCRIPTION OF DRAWINGS

FIG. 1 is a perspective view depicting a general configuration example of a semiconductor laser element used as a semiconductor apparatus according to a first embodiment.

FIG. 2 is a diagram depicting a crystal structure of a hexagonal group-III nitride semiconductor (1).

FIG. 3 is a diagram depicting the crystal structure of the hexagonal group-III nitride semiconductor (2).

FIG. 4 is a diagram depicting the crystal structure of the hexagonal group-III nitride semiconductor (3).

FIG. 5 is a cross-sectional view depicting a general cross section structure example of a semiconductor laser element according to the first embodiment in a thickness direction.

FIG. 6 is a diagram illustrating a step of cleaving a wafer.

FIG. 7 is a diagram illustrating one of problems occurring in a case where a linear long guide groove that extends continuously along a boundary for cleavage is formed.

FIG. 8 is a diagram illustrating one of problems occurring in a case where the linear long guide groove extending continuously along the boundary for cleavage is segmented.

FIG. 9 is a flowchart depicting an example of a general manufacturing process for the semiconductor laser element according to the first embodiment.

FIG. 10 is a diagram depicting an example of a wafer provided with P surface guide grooves according to the first embodiment.

FIG. 11 is a diagram depicting a general configuration example of the wafer provided with N surface scribes according to the first embodiment as viewed from an N surface side.

FIG. 12 is an enlarged view of a partial region in FIG. 11.

FIG. 13 is a diagram depicting a cross section structure example of the wafer that is provided with the N surface scribes according to the first embodiment and that has been cut at a surface perpendicular to a resonator length direction along a scribe line.

FIG. 14 is a diagram depicting a cross section structure near the cleavage surface of the semiconductor laser element resulting from cleavage according to the first embodiment.

FIG. 15 is a diagram illustrating a step of cleaving the wafer provided with the N surface scribes according to the first embodiment.

FIG. 16 is a diagram illustrating a step of cleaving a wafer provided with a linear long guide groove extending continuously along the boundary for cleavage.

FIG. 17 is a diagram depicting a positional relation between the P surface guide grooves and the N surface scribes according to the first embodiment (1).

FIG. 18 is a diagram depicting the positional relation between the P surface guide grooves and the N surface scribes according to the first embodiment (2).

FIG. 19 is a diagram depicting the positional relation between the P surface guide grooves and the N surface scribes according to the first embodiment (3).

FIG. 20 is a diagram depicting a part of a cross section structure example of a wafer that is provided with semiconductor laser elements according to a second embodiment and that has been cut along a scribe line.

FIG. 21 is a diagram depicting a part of a configuration example of the wafer provided with the semiconductor laser elements according to the second embodiment as viewed from the N surface side.

FIG. 22 is a cross-sectional view depicting an example of N surface scribes according to a third embodiment.

FIG. 23 is a cross-sectional view depicting another example of the N surface scribes according to the third embodiment.

FIG. 24 is a cross-sectional view depicting yet another example of the N surface scribes according to the third embodiment.

FIG. 25 is a diagram depicting a cross section structure example of a wafer that is provided with N surface scribes and through-holes according to a fourth embodiment and that has been cut at a surface perpendicular to the resonator length direction along the scribe line.

FIG. 26 is a diagram depicting a cross section structure example of a wafer that is provided with N surface scribes and P surface guide grooves according to a fifth embodiment and that has been cut at a surface perpendicular to the resonator length direction along the scribe line.

FIG. 27 is a cross-sectional view depicting an example of P surface guide grooves according to a sixth embodiment.

FIG. 28 is a cross-sectional view depicting another example of the P surface guide grooves according to the sixth embodiment.

FIG. 29 is a diagram depicting a cross section structure example of a wafer that is provided with N surface scribes according to a seventh embodiment and that has been cut at a surface perpendicular to the resonator length direction along the scribe line.

FIG. 30 is a diagram depicting a general configuration example of the wafer provided with the N surface scribes according to the seventh embodiment as viewed from the N surface side.

FIG. 31 is a diagram depicting a cross section structure example of a wafer that is provided with N surface scribes according to an eighth embodiment and that has been cut at a surface perpendicular to the resonator length direction along the scribe line.

FIG. 32 is a diagram depicting a general configuration example of the wafer provided with the N surface scribes according to the eighth embodiment as viewed from the N surface side.

FIG. 33 is a diagram depicting a cross section structure example of a wafer that is provided with N surface scribes according to a ninth embodiment and that has been cut at a surface perpendicular to the resonator length direction along the scribe line.

FIG. 34 is a diagram depicting a general configuration example of the wafer provided with the N surface scribes according to the ninth embodiment as viewed from the N surface side.

### DESCRIPTION OF EMBODIMENTS

Embodiments of the present disclosure will be described below in detail on the basis of the drawings. Note that, in the embodiments below, the same portions are assigned the same reference signs and duplicate description is omitted.

Further, the present disclosure is described in the order of items listed below.

1. First Embodiment
1.1 Structure of Semiconductor Laser Element
1.2 Semiconductor Substrate
1.3 Cross Section Structure of Semiconductor

Laser Element
1.4 Manufacturing Method
   1.4.1 Problems with Manufacturing Process
   1.4.2 Overall Flow
   1.4.3 Laser Ablation Processing
1.5 P Surface Guide Grooves
1.6 N Surface Scribes
1.7 Operations and Effects

2. Second Embodiment

3. Third Embodiment

4. Fourth Embodiment

5. Fifth Embodiment

6. Sixth Embodiment

7. Seventh Embodiment

8. Eighth Embodiment

9. Ninth Embodiment

### 1. First Embodiment

First, a semiconductor apparatus and a method for manufacturing the semiconductor apparatus according to a first embodiment will be described in detail with reference to the drawings.

### 1.1 Structure of Semiconductor Laser Element

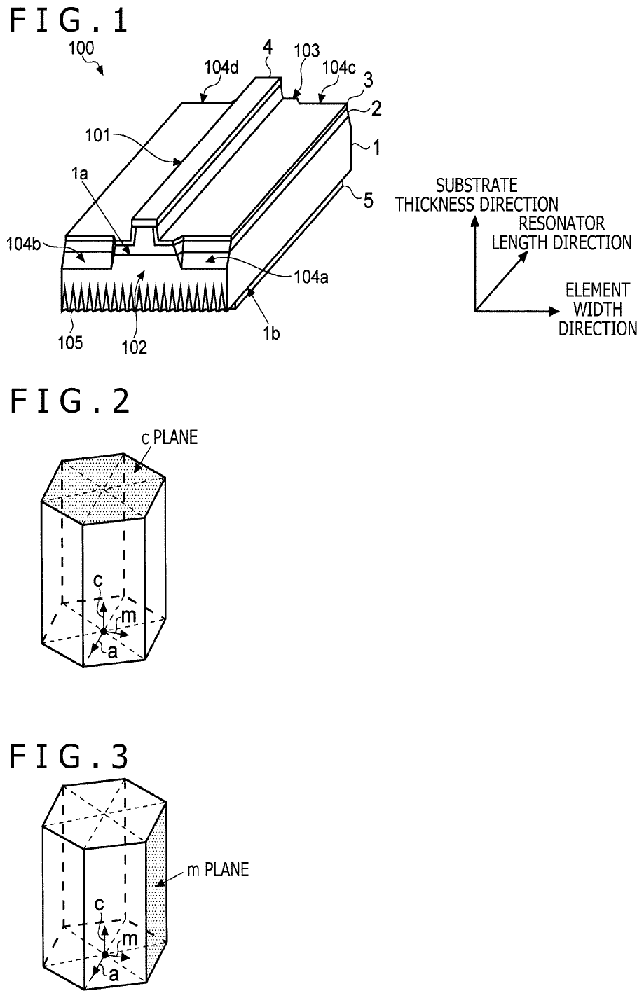

FIG. 1 is a perspective view depicting a general configuration example of a semiconductor laser element used as a semiconductor apparatus according to the present embodiment. Note that the semiconductor apparatus according to the present disclosure is not limited to the semiconductor laser element and can be any of various semiconductor apparatuses including side surfaces at least one of which includes a cleavage surface, for example, light emitting elements such as LEDs (Light Emitting Diodes). Further, in the example depicted in FIG. 1, a ridge (index-guided) semiconductor laser element 100 is illustrated. However, the present disclosure is not limited to this configuration. For example, the technique of the present disclosure described below can be applied to various semiconductor apparatuses such as gain-guided semiconductor laser elements.

As depicted in FIG. 1, the semiconductor laser element 100 includes a semiconductor substrate 1, an epitaxial layer 2, an insulating layer 3, a first electrode 4, and a second electrode 5.

In the present embodiment, for example, a hexagonal group-III nitride semiconductor is used as the semiconductor substrate 1. Further, the semiconductor substrate 1 may be an inclined substrate such as a semi-polar substrate.

In the semiconductor laser element 100, one surface (in FIG. 1, an upper surface) of the semiconductor substrate 1 is a semi-polar surface 1a, and the epitaxial layer 2, the insulating layer 3, and the first electrode 4 are provided on the semi-polar surface 1a in this order. Further, the second electrode 5 is provided on a surface (in FIG. 1, a lower surface; hereinafter referred to as a back surface) 1b of the semiconductor substrate 1 opposite to the semi-polar surface 1a.

In addition, as depicted in FIG. 1, the semiconductor laser element 100 is shaped like a substantially rectangular parallelepiped, and the first electrode 4-side surface of the semiconductor laser element 100 is provided with a stripe portion 101 of a ridge structure extending in a resonator length direction. Note that the resonator length direction is a direction in which laser light travels back and forth in the semiconductor laser element 100.

The stripe portion 101 is formed to extend from one side surface (resonator end surface 102 described later) to the other side surface (resonator end surface 103 described later) of the semiconductor laser elements 100. An extension direction of the stripe portion 101 is the propagation direction of laser light (resonator length direction). Further, a region of the epitaxial layer 2 corresponding to the stripe portion 101 corresponds to an optical waveguide.

Note that, in the present embodiment, the extension direction of the stripe portion 101 is assumed to be a direction orthogonal to an a-axis direction in a hexagonal group-III nitride semiconductor. However, the extension direction of the stripe portion 101 is not limited to this example, and can be set as appropriate, for example, depending on such conditions as an intended use and required laser characteristics.

The stripe portion 101 may have a width of, for example, several to several dozen μm or less, and the stripe portion 101 may have an extension length (resonator length) of, for example, approximately several hundred μm.

Further, the semiconductor laser element 100 includes four side surfaces (end surfaces), and two of the four side surfaces orthogonal to the extension direction of the stripe portion 101 (resonator length direction in FIG. 1) act as reflection surfaces of a laser resonator (the two side surfaces are cleavage surfaces). Specifically, the two side surfaces are the resonator end surfaces 102 and 103, and the two resonator end surfaces 102 and 103 and an optical waveguide region in the epitaxial layer 2 corresponding to the stripe portion 101 constitute a laser resonator.

A dielectric multilayer film such as an SiO₂/TiO₂ film may be provided on at least one surface of the two resonator end surfaces 102 and 103. Such an end surface coat allows reflectance at the resonator end surface to be adjusted.

Note that, in the present embodiment, four inclined surface portions 104a to 104d are provided in the respective four corners of the stripe portion 101-side surface (in FIG. 1, the upper surface) of a laser structure including the semiconductor substrate 1, the epitaxial layer 2, and the insulating layer 3. In a production substrate of the semiconductor laser element 100, each of the inclined surface portions 104a to 104d is a part (remaining part) of one of side wall surfaces that are provided on a scribe line in a direction along the resonator end surfaces 102 and 103 (element width direction in FIG. 1) and that define a groove with a generally V-shaped cross section (corresponding to a P surface guide groove described later). In other words, each of the inclined surface portions 104a and 104b is the remaining part of one of the side wall surfaces defining the P surface guide groove, and each of the inclined surface portions 104c and 104d is the remaining part of the other of the side wall surfaces defining the P surface guide groove. Consequently, each of the inclined surface portions 104a to 104d extends from the upper surface toward the back surface (corresponding to a back surface 1b of the semiconductor substrate 1) of the laser structure.

For example, in a case where the semi-polar surface 1a has a plane orientation near a {20-21} plane, a {0001} plane (c plane) is mostly exposed from one of the inclined surface portions 104a and 104b and one of the inclined surface portions 104c and 104d. In this case, in the extension direction of the stripe portion 101 (resonator length direction in FIG. 1; corresponding to a groove width direction of the P surface guide groove described below), the ratio between the width of the inclined surface portion from which the c plane is not exposed and the width of the inclined surface portion from which the c plane is exposed is, for example, approximately 6:4. In other words, the ratio between the width of the inclined surface portion 104c and the width of 104d is offset from 1:1.

Further, each of the resonator end surfaces 102 and 103 in the semiconductor laser element 100 is provided with plural groove-like machining traces 105 formed from the back surface 1b side of the semiconductor substrate 1 to the middle of each of the resonator end surfaces 102 and 103. The groove-like machining traces 105 are machining traces of grooves (corresponding to N surface scribes described later) for controlling stress during cleavage such that the cleavage surface used for cleaving the production substrate of the semiconductor laser element 100 forms a desired surface (for example, a surface substantially perpendicular to the semi-polar surface 1a). The groove-like machining traces 105 are, for example, semi-conical or semi-elliptic-conical grooves with a diameter decreasing from the back surface 1b of the semiconductor substrate 1 toward the semi-polar surface 1a. Consequently, the groove-like machining traces 105 are each shaped like a semi-circle or a semi-ellipse as viewed from the back surface 1b. Further, in a case where the back surface 1b side is designated as a bottom side, a top portion of each groove-like machining trace 105 may be pointed to have an acute angle of 30° or less, for example. Note that the details of the groove-like machining traces 105 and N surface scribes will be described later.

### 1.2 Semiconductor Substrate

In the configuration described above, for example, a hexagonal group-III nitride semiconductor such as GaN, AlN, AlGAN, InGAN, or InAlGaN is used for the semiconductor substrate 1. Further, for example, a substrate involving carriers with an n-type conductivity is used as the semiconductor substrate 1. However, this is not restrictive, and a substrate involving carriers with a p-type conductivity may be used as the semiconductor substrate 1.

Further, in the present embodiment, the one surface of the semiconductor substrate 1 provided with the epitaxial layer 2, the insulating layer 3, and the first electrode 4 is the semi-polar surface 1a as described above. The semi-polar surface 1a is, for example, a surface with the p-type conductivity. However, this is not restrictive, and the semiconductor substrate 1 can be configured such that a surface with the n-type conductivity (hereinafter also referred to as an N surface) is provided with the epitaxial layer 2, the insulating layer 3, and the first electrode 4.

In this regard, FIGS. 2 to 4 depict a crystal structure of a hexagonal group-III nitride semiconductor. Note that FIGS. 2 to 4 illustrate a case of using gallium nitride (GaN) as a hexagonal group-III nitride semiconductor.

As depicted in FIGS. 2 and 3, in the hexagonal group-III nitride semiconductor, a piezo electric field is generated in a light emission layer described later in the epitaxial layer 2, along a c-axis. Thus, the c plane ({0001} plane) orthogonal to the c-axis has polarity and is also referred to as a polar plane. On the other hand, an m plane ({10-10} plane) orthogonal to an m-axis is parallel to the c axis and thus has no polarity and is also referred to as a non-polar plane. In contrast, the structure includes a plane having, as a normal direction, an axial direction corresponding to the c-axis tilted through a predetermined angle in the m-axis direction, for example, in the example illustrated in FIG. 4, a plane ({20-21} plane) having, as a normal direction, an axial direction corresponding to the c-axis tilted through 75° in the m-axis direction, the plane corresponding to an intermediate plane between the c plane and the m plane and also being referred to as a semi-polar plane.

Note that, as the semi-polar surface 1a, for example, a crystal plane that has a normal direction corresponding to the c-axis tilted 45° to 80° or 100° to 135° in the m-axis direction may be used. Further, within the above-described range of angles, the angle between the normal direction of the semi-polar surface 1a and the c-axis preferably ranges, for example, from 63° to 80° or from 100° to 117°, in order to achieve emission of light with a large wavelength. Within these ranges of angles, piezo polarization in the light emission layer (active layer) described later in the epitaxial layer 2 is reduced, and indium (In) atoms are successfully captured during growth (formation) of the light emission layer, enabling extension of the variable range of In composition in the light emission layer. Consequently, the above-described range of angles between the normal direction of the semi-polar surface 1a and the c-axis facilitates emission of light with a large wavelength.

As the semi-polar surface 1a having the normal direction within the above-described ranges of angles, for example, a crystal plane such as a {20-21} plane, a {10-11} plane, a {20-2-1} plane, or a {10-1-1} plane can be used. Note that a crystal plane slightly inclined approximately ±4° from each of the above-described crystal planes can also be used as the semi-polar surface 1a. In a case where any of these crystal planes is used as the semi-polar surface 1a, the resonator end surfaces 102 and 103 with sufficiently high flatness and orthogonality can be formed.

### 1.3 Cross Section Structure of Semiconductor Laser Element

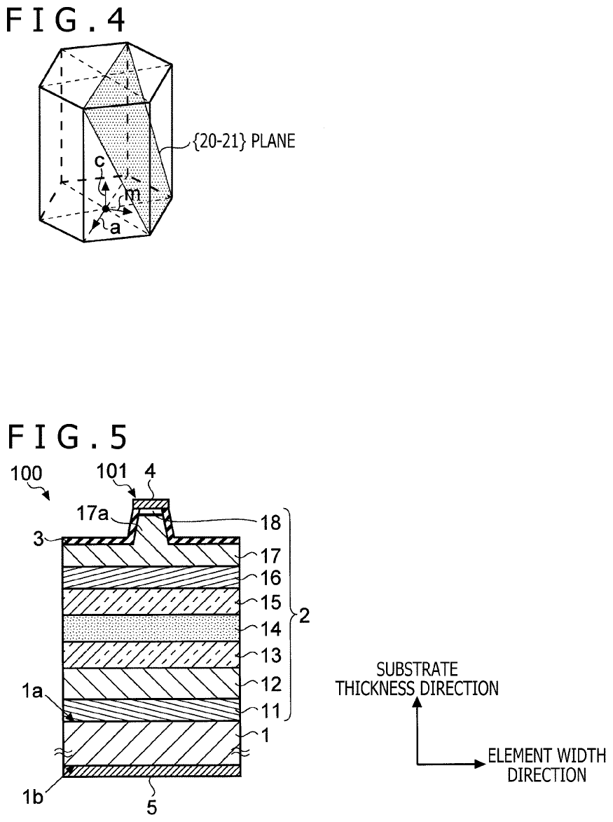

Now, a cross section structure example of the semiconductor laser element 100 according to the present embodiment will be described in detail with reference to FIG. 5. FIG. 5 is a cross-sectional view depicting a general cross section structure example of the semiconductor laser element according to the present embodiment in the thickness direction (substrate thickness direction in FIG. 5). Note that FIG. 5 depicts a cross section orthogonal to the extension direction (resonator length direction in the figure) of the stripe portion 101.

As depicted in FIG. 5, the semiconductor laser element 100 includes, as a laser structure, a semiconductor chip including the semiconductor substrate 1, the epitaxial layer 2 provided on the semi-polar surface 1a of the semiconductor substrate 1, and the insulating layer 3 formed on the epitaxial layer 2. Further, the semiconductor laser element 100 includes the first electrode 4 provided on the stripe portion 101 in the upper portion of the epitaxial layer 2 and the second electrode 5 provided on the back surface 1b of the semiconductor substrate 1. Note that an example in which the semiconductor substrate 1 includes an n-type GaN semi-polar substrate will be described but the semiconductor substrate 1 is not limited to the n-type GaN semi-polar substrate and may be changed to any of various substrates, for example, a p-type GaN semi-polar substrate.

The epitaxial layer 2 is a laminate structure provided in the semi-polar surface 1a (first surface) of the semiconductor substrate 1 and includes, for example, a buffer layer 11, a first clad layer 12, a first light guide layer 13, a light emission layer 14 (active layer), a second light guide layer 15, a carrier block layer 16, a second clad layer 17, and a contact layer 18 arranged in this order from a bottom layer.

The buffer layer 11 can include, for example, a gallium nitride-based semiconductor layer such as an n-type GaN layer. The first clad layer 12 can include, for example, a gallium nitride-based semiconductor layer such as an n-type AlGaN layer or an n-type InAlGaN. Further, the first light guide layer 13 can include, for example, a gallium nitride-based semiconductor layer such as an n-type GaN layer or an n-type InGaN layer.

The light emission layer 14 includes, for example, a well layer (not illustrated) including a gallium nitride-based semiconductor such as InGaN or InAlGaN and a barrier layer (not illustrated) including a gallium nitride-based semiconductor such as GaN, InGaN, or InAlGaN. Note that the structure of the light emission layer 14 may be, for example, a multi-quantum well structure including plural well layers and plural barrier layers alternately laminated together. Note that the light emission layer 14 is a light emission region in the epitaxial layer 2.

The second light guide layer 15 can include a p-type gallium nitride-based semiconductor layer involving carriers with the p-type conductivity and can include, for example, a gallium nitride-based semiconductor layer such as a p-type GaN layer or a p-type InGaN layer. The carrier block layer 16 (electron block layer) can include, for example, a p-type AlGaN layer.

The second clad layer 17 can include, for example, a gallium nitride-based semiconductor layer such as a p-type AlGaN layer or a p-type InAlGaN layer. Note that, in the second embodiment, the semiconductor laser element 100 is of a ridge type and the entire region of the first electrode 4-side surface of the second clad layer 17 other than the region of the first electrode 4-side surface corresponding to the stripe portion 101 has been chipped away by etching processing or the like. Thus, a ridge portion 17a is provided in the region of the first electrode 4-side surface of the second clad layer 17 corresponding to the stripe portion 101. Note that, similarly to the stripe portion 101, the ridge portion 17a is provided extending in a direction substantially orthogonal to each resonator end surface and extending from one resonator end surface 102 to the other resonator end surface 103.

The contact layer 18 can include, for example, a p-type GaN layer. Further, the contact layer 18 is provided on the ridge portion 17a of the second clad layer 17.

The insulating layer 3 includes, for example, an insulating layer such as an SiO₂ film. As depicted in FIG. 5, the insulating layer 3 is provided on the entire region of the second clad layer 17 other than the ridge portion 17a and on side surfaces of the ridge portion 17a and the contact layer 18.

The first electrode 4 (p-side electrode) can include, for example, a conductive film such as a Pd film. Further, the first electrode 4 is provided on the contact layer 18 and a contact layer 18-side end surface of the insulating layer 3. Note that, in the semiconductor laser element 100 according to the present embodiment, an electrode film for a pad electrode may be provided over the insulating layer 3 and the first electrode 4.

The second electrode 5 (n-side electrode) can include, for example, a conductive film such as an Al film. Further, the second electrode 5 is provided on the back surface 1b of the semiconductor substrate 1.

### 1.4 Manufacturing Method

Now, a method for manufacturing the semiconductor laser element 100 according to the present embodiment will be described in detail with reference to the drawings.

1.4.1 Problems with Manufacturing Process

In general manufacture of a semiconductor laser element for which a hexagonal group-III nitride semiconductor is used, an epitaxial layer is formed on a semi-polar surface of a wafer-like semiconductor substrate by crystal growth using, for example, an MOCVD (Metal Organic Chemical Vapor Deposition) method or the like. Then, on an upper surface of the epitaxial layer, a ridge portion is formed for use as an optical waveguide or for current constriction. Subsequently, as a configuration for passing a current through a semiconductor substrate, an electrode is formed on the upper surface of the epitaxial layer (hereinafter referred to as the P surface) and on a back surface of the semiconductor substrate (hereinafter referred to as the N surface).

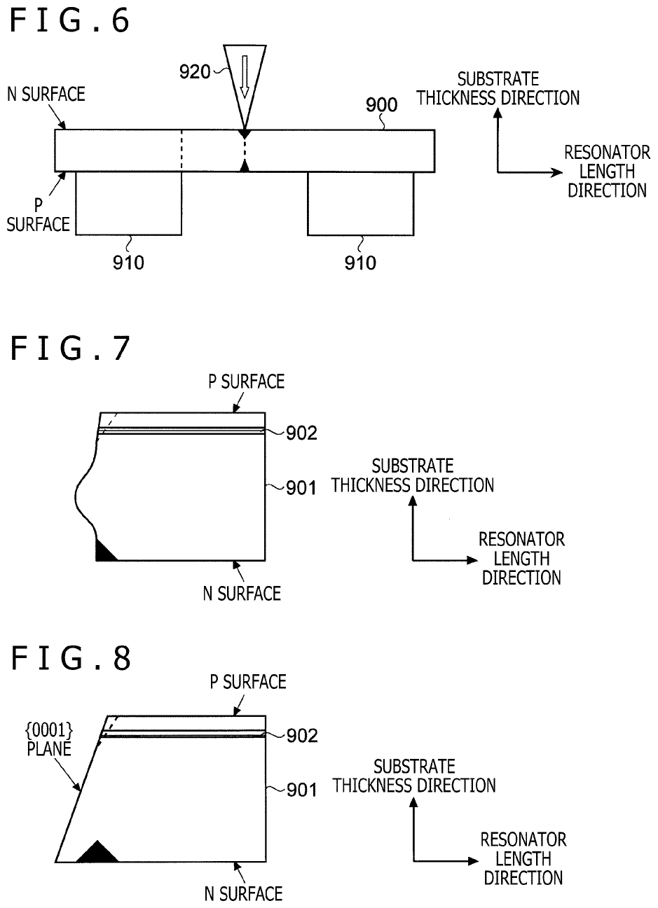

Then, as illustrated in FIG. 6, a wafer 900 on which plural semiconductor laser elements are formed as described above is placed on a pair of blade rests 910 with the P surface facing downward. A breaking apparatus 920 referred to as a blade is used to press the wafer 900 to apply local stress to the wafer 900, thus cleaving the wafer along a boundary (scribe line) forming resonator end surfaces. This splits the wafer into plural bar-like chips on each of which plural semiconductor laser elements are arranged along an element width direction. Note that cleavage surfaces resulting from the cleavage constitute resonator end surfaces of the semiconductor laser element.

However, when the resonator end surfaces of the semiconductor laser element are formed, the semiconductor laser element being produced by crystal growth on the semi-polar surface of the semiconductor substrate for which the hexagonal group-III nitride semiconductor is used, in a case where conditions equivalent to known scribe conditions for a {0001} plane or the like are used, cracking is developed under the significant effect of a sliding plane ({0001} plane) corresponding to a substrate crystal plane near the cleavage position (also referred to as a basal plane), making it difficult to form a cleavage plane near a light emission layer 902 perpendicularly to the resonator length direction.

A possible method for solving such a problem is to form a groove in the P surface or in both the P surface and the N surface along the boundary for cleavage to guide the cleavage in such a manner that the cleavage surface forms desired surfaces (the groove is hereinafter referred to as a guide groove).

Further, forming a deeper guide groove in the N surface may be effective for obtaining more perpendicular resonator end surfaces.

However, in laser ablation processing, laser light is absorbed and changed into heat to form a groove in the semiconductor substrate, and thus, obtaining processing depth requires higher energy, leading to a phenomenon in which the opening of the groove is enlarged in the outermost surface (N surface) that is first exposed to laser.

Further, for example, a linear long guide groove extending continuously along the boundary for cleavage may be formed in the N surface. Such a processing shape, however, leads to cracking (basal plane dislocation) developing from the N surface side of the semiconductor substrate 901, as depicted in FIG. 7, for example, and the crack having developed is significantly affected near a light emission layer 902 by a {20-21} plane forming a foundation. As a result, there is a risk that the perpendicularity of the resonator end surfaces is impaired, leading to degraded laser characteristics. Thus, there is a problem in that the guide groove formed in the N surface fails to be made deeper.

Further, in a case where a linear long guide groove extending continuously along the boundary for cleavage is formed in the N surface, instead of or in addition to an intended scribe line, another scribe line may be formed during cleavage.

There is another problem. For example, in a case where a linear guide groove extending continuously along the boundary for cleavage is segmented to form a partial region in which no guide groove is formed, the effect of the guide groove formed on the N surface side fails to be produced sufficiently. Accordingly, for example, as illustrated in FIG. 8, cracking develops from the P surface side of the semiconductor substrate 901 along the {0001} plane. Consequently, the perpendicularity of the resonator end surfaces is impaired, resulting in degraded laser characteristics.

As described above, there is a problem in that mere formation of a guide groove on the N surface side leads to difficulty in compatible achievement of both reduction of development of cracking from the N surface side and acquisition of stably perpendicular resonator end surfaces. As a result, the perpendicularity of the resonator end surfaces fails to be achieved sufficiently, leading to a substantial reduction in reflectance or a waveguide loss, and a problem occurs in that a threshold current Ith and slope efficiency required for laser oscillation are degraded, resulting in degraded laser characteristics. Further, another problem occurs in that a decrease in light conversion efficiency at a constant current shortens the lifetime of elements during long-term operation.

Thus, in the present embodiment, guide grooves (hereinafter referred to as N surface scribes) are intermittently formed on the N surface at short intervals as described below. Formation of such N surface scribes intermittently repeated at short intervals enables suppression of unintended development of cracking from the N surface side, allowing deeper scribes to be formed. As a result, the perpendicularity of the resonator end surfaces can be improved, suppressing degradation of the laser characteristics.

Further, intermittent formation of N surface scribes at short intervals enables significant shortening of the region where no scribes are present between N surface scribes, and thus the effect of the N surface scribes can be allowed to be fully exerted to achieve the perpendicularity of the resonator end surfaces.

### 1.4.2 Overall Flow

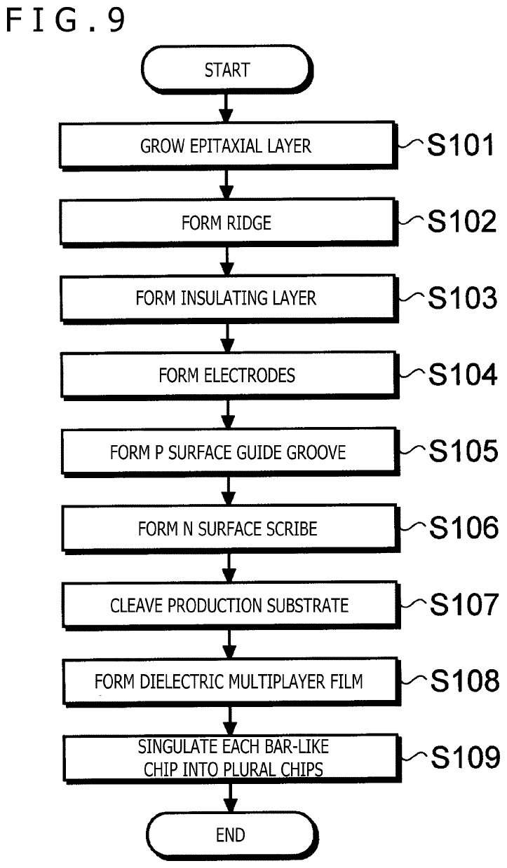

Now, a manufacturing process for the semiconductor laser element 100 according to the present embodiment will be described in detail with reference to FIG. 9. FIG. 9 is a flowchart illustrating an example of a general manufacturing process for the semiconductor laser element according to the present embodiment.

As depicted in FIG. 9, in the present manufacturing process, first, an epitaxial layer 2 is formed on the semi-polar surface 1a of the semiconductor substrate 1 including a hexagonal group-III nitride semiconductor, by using, for example, a technique such as the MOCVD method to epitaxially grow various semiconductor films in a predetermined order (step S101). Specifically, semiconductor films constituting the following layers are epitaxially grown on the semi-polar surface 1a in the following order: the buffer layer 11, the first clad layer 12, the first light guide layer 13, the light emission layer 14, the second light guide layer 15, the carrier block layer 16, the second clad layer 17, and the contact layer 18. Note that the semiconductor substrate 1 may be treated in advance by thermal cleaning or the like.

Then, a mask is formed in a formation region of the stripe portion 101 on the uppermost surface (hereinafter referred to as the P surface) of the semiconductor substrate 1 on which the epitaxial layer 2 is formed. Subsequently, the entire region of the P surface other than the region in which the mask is formed is etched to form a ridge portion 17a on the contact layer 18-side surface of each semiconductor laser element 100 (step S102). Note that the P surface may, for example, be a surface with the p-type conductivity.

Specifically, the entire region other than the formation region of the stripe portion 101 is chipped away from the front surface of the contact layer 18 to a predetermined depth of the second clad layer 17 to form the ridge portion 17a in the formation region of the stripe portion 101. At this time, the ridge portion 17a is formed continuously along the extension direction of the stripe portion 101 in such a manner as to extend across the formation region of the semiconductor laser element 100 adjacent in the extension direction of the stripe portion 101, in other words, to traverse the boundary forming the resonator end surfaces 102 and 103.

Then, the mask on the ridge portion 17a is removed, and, for example, a technique such as a deposition method or a sputtering method is used to form an insulating layer constituting the insulating layer 3 on the entire P surface on which the ridge portion 17a is formed (step S103). Note that the removal of the mask on the ridge portion 17a may follow the formation of the insulating layer. Further, in a case where the mask is formed using, for example, metal, the mask can be used as a part of the first electrode 4 rather than being removed.

Then, electrode films constituting the first electrode 4 and the second electrode 5 are formed on the production substrate including the semiconductor substrate 1 on which the epitaxial layer 2 and the insulating layer 3 including the ridge portion 17a are formed as described above (step S104).

Specifically, the electrode film (first electrode film) constituting the first electrode 4 is formed as follows. First, a photolithography technique and an etching technique are used to remove the insulating layer on each ridge to expose the contact layer 18 at the front surface. Then, for example, a technique such as liftoff is used to form, on each contact layer 18 exposed, an electrode film constituting the first electrode 4.

On the other hand, an electrode film (second electrode film) constituting the second electrode 5 is formed as follows. First, the back surface 1b of the semiconductor substrate 1 is polished to set the thickness of the semiconductor substrate 1 to a desired thickness. Then, for example, a technique such as the deposition method or the sputtering method is used to form, on the back surface 1b of the semiconductor substrate 1, the electrode film constituting the second electrode 5. Note that the electrode film formed in the region in which the N surface scribes are to be formed in the subsequent step S106 may be removed, for example, by a method such as liftoff.

Steps S101 to S104 described above are executed to form plural semiconductor laser elements 100 arranged in a two-dimensional pattern on wafer which has not been singulated yet.

Then, P surface guide grooves along which the cleavage surface is guided during singulation are formed in the P surface which is the uppermost surface of the wafer, along the boundary (scribe line) between the formation regions of the semiconductor laser elements 100 adjacent to each other in the propagation direction of laser light (step S105).

The P surface guide grooves can be formed using, for example, the photolithography technique and the etching technique. Further, the P surface guide grooves are formed in the P surface of the wafer along the boundary (resonator end surface-side boundary; corresponding to the scribe line) in a direction orthogonal to the propagation direction of laser light (extension direction of the stripe portion 101). Further, each of the P surface guide grooves is formed in the P surface of the wafer in a partial region including at least one corner of each semiconductor laser element 100. However, the P surface guide groove is formed in a region that does not intersect the stripe portion 101, which traverses the boundary forming the resonator end surfaces 102 and 103. In other words, in step S105, the P surface guide grooves are intermittently formed along each boundary forming the resonator end surfaces 102 and 103.

Then, in the present embodiment, plural N surface scribes arranged along the boundary (scribe line) forming the resonator end surfaces 102 and 103 are, for example, formed in the back surface 1b of the semiconductor substrate 1 on which the second electrode 5 is formed (step S106). For example, laser ablation can be used to form the N surface scribes along the scribe line. Specifically, the production substrate produced is installed in a laser scribe apparatus and intermittently irradiated with a laser pulse along the scribe line, to form plural N surface scribes arranged along the scribe line.

Then, a braking apparatus (not illustrated) referred to as a blade is pressed against the region of the back surface 1b of the production substrate in which the N surface scribes are formed (corresponding to the region facing the region on the P surface side of the production substrate in which the P surface guide groove is formed), thus applying stress to the region. Accordingly, the production substrate is cleaved along the boundary (scribe line) forming the resonator end surfaces 102 and 103 (step S107). Then, the cleavage processing is repeated for each boundary forming the resonator end surfaces 102 and 103, to divide the production substrate into plural bar-like chips on each of which plural semiconductor laser elements 100 are arranged along a direction (element width direction) perpendicular to the resonator length direction.

Note that, for example, similarly to the cleavage illustrated using FIG. 6, the cleavage in step S107 is performed by placing the wafer on a pair of blade rests with the P surface of the wafer facing downward and by pressing the breaking apparatus against the wafer from the N surface side to apply local stress to the wafer.

In such cleavage, due to the N surface scribes formed in the back surface 1b of the semiconductor substrate 1 and the P surface guide grooves formed in the P surface of the production substrate, the stress during cleavage concentrates near the stripe portion 101, and thus the resonator end surfaces 102 and 103 are accurately formed at the desired positions near the stripe portion 101. Accordingly, the resonator end surfaces 102 and 103 with high flatness and high orthogonality can be obtained.

Then, a dielectric multilayer film is formed on the cleavage surfaces (resonator end surfaces) of each of the bar-like chips resulting from the cleavage in step S107 described above (step S108). Then, each bar-like chip is cut along boundaries between the semiconductor laser elements 100 arranged in the element width direction and thus singulated into chips of the plural semiconductor laser elements 100 (step S109). Accordingly, the semiconductor laser element 100 as illustrated in FIG. 1 is manufactured.

### 1.4.3 Laser Ablation Processing

Note that the laser ablation processing used to form the N surface scribes in step S106 in FIG. 9 can be performed using laser light of 355 nm (nanometers) corresponding to a wavelength that is likely to be absorbed by the hexagonal group-III nitride semiconductor, in a case where, for example, a hexagonal group-III nitride semiconductor is used as the semiconductor substrate 1.

Further, in the laser ablation processing, pulsed laser light output from a laser oscillator is focused by an optical system such as a lens and radiated to a wafer corresponding to a processing target. The laser light focused on the wafer is absorbed by the wafer and thus changed into thermal energy. A region of wafer irradiated with the laser light is vaporized by the thermal energy. As a result, in the region of the wafer irradiated with the laser light, formed are N surface scribes each of which has a diameter, a depth, and a shape corresponding to the energy (laser power), pulse shape, and irradiation direction of the laser light.

For example, laser light with low power forms shallow N surface scribes, whereas laser light with high power forms deep N surface scribes. Further, laser light with a short pulse forms N surface scribes in a conical shape or an elliptic conical shape having a minor axis corresponding to the scanning direction of the laser light. Laser light with a long pulse forms N surface scribes in an elliptic conical shape having a major axis corresponding to the scanning direction of the laser light.

Further, in the laser ablation processing, by using a high-speed shutter or the like and opening and closing the shutter during scanning, a region in which N surface scribes are formed and a region in which no N surface scribes are formed can be disposed alternately.

Furthermore, in a case where the processing depth is adjusted by the high speed of the N surface scribes, an acousto-optic modulator (AOM) or the like can be used. By using the AOM and adjusting the intensity of laser light, the N surface scribes can be made continuously deeper or shallower. For example, the use of the AOM enables N surface scribes to be formed in such a manner that the machining traces of the N surface scribes are shaped like triangles, trapezoids, or the like as observed laterally after division in the same direction as the scanning direction.

### 1.5 P Surface Guide Grooves

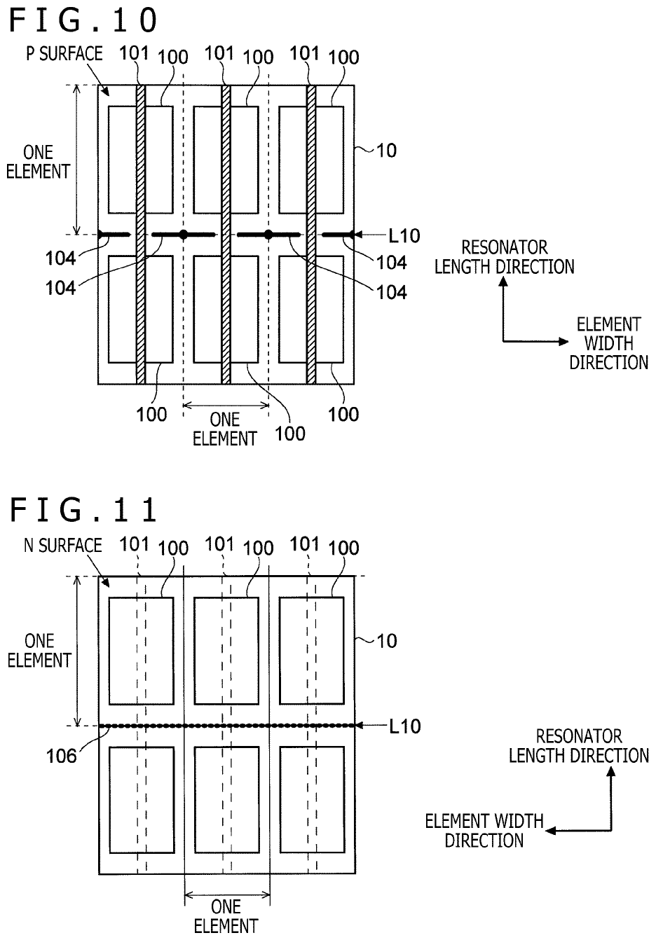

FIG. 10 is a diagram illustrating an example of a wafer provided with the P surface guide grooves according to the present embodiment, for example, a diagram depicting a state following step S105 or S106 in FIG. 9. Note that FIG. 10 depicts the configuration of the wafer as viewed from the P surface side. Further, the wafer depicted in FIG. 10 corresponds to a partial region in the entire wafer, and in reality, includes a larger number of the semiconductor laser elements 100 arranged in a two-dimensional grid pattern.

As depicted in FIG. 10, plural the semiconductor laser elements 100 are produced and arranged on a wafer 10 in a two-dimensional grid pattern. P surface guide grooves 104 are, for example, provided along a scribe line L10 set between the adjacent semiconductor laser elements 100 on the P surface of the wafer 10. Note that the scribe line L10 is set, for example, along a direction (corresponding to the element width direction) orthogonal to the extension direction (corresponding to the resonator length direction) of the stripe portion 101 corresponding to the propagation direction of laser light.

Further, each of the P surface guide grooves 104 is provided in the P surface of the wafer 10 in a partial region including at least one corner of each semiconductor laser element 100. However, the P surface guide grooves 104 are formed intermittently such that each P surface guide groove 104 does not intersect the stripe portion 101, which traverses the boundary forming the resonator end surfaces 102 and 103.

The groove shape of the P surface guide groove 104 as viewed in the element width direction may be, for example, a general V shape. Moreover, the groove shape of the P surface guide groove 104 as viewed in the resonator length direction may be, for example, a general trapezoidal shape. Further, the shape of a stripe portion 101-side end (tip) of the P surface guide groove 104 is, for example, a general V shape as viewed from the P surface side.

Further, the width of the P surface guide groove 104 in the resonator length direction may be set to range from approximately 0.1 to 5 μm and more preferably from approximately 0.1 to 2.0 μm. Furthermore, the depth of the P surface guide groove 104 may be set to range, for example, from approximately 0.5 to 30 μm and more preferably from approximately 1.0 to 25.0 μm.

### 1.6 N Surface Scribes

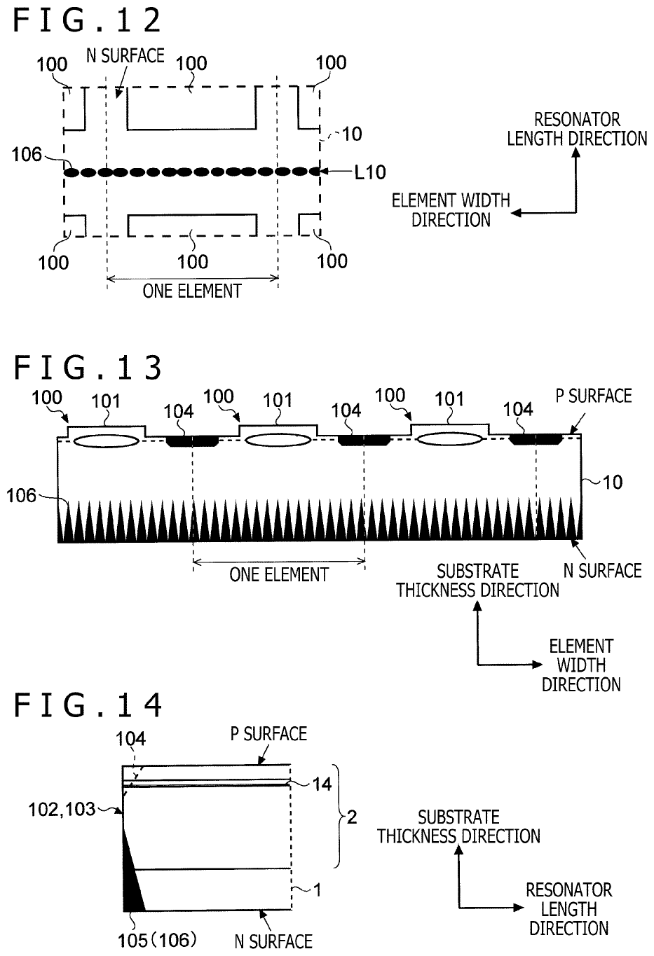

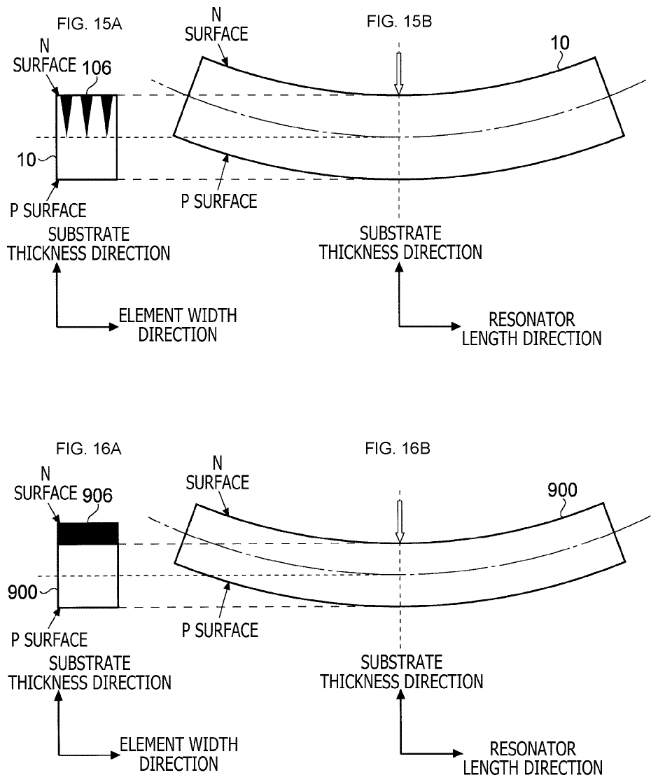

FIG. 11 is a diagram depicting a general configuration example of the wafer provided with the N surface scribes according to the present embodiment as viewed from the N surface side, for example, a diagram illustrating a state following step S105 or S106 in FIG. 9. Further, FIG. 12 is an enlarged view of a partial region in FIG. 11. FIG. 13 is a diagram depicting a cross section structure example of the wafer that is provided with the N surface scribes according to the present embodiment and that has been cut at a surface perpendicular to the resonator length direction, along the scribe line. FIG. 14 is a diagram depicting a cross section structure near the cleavage surface in the semiconductor laser element resulting from cleavage. Note that the wafer depicted in FIG. 11 and FIG. 13 is a partial region in the entire wafer, and in reality, includes a larger number of the semiconductor laser elements 100 arranged in a two-dimensional grid pattern.

As depicted in FIGS. 11 to 13, plural N surface scribes 106 are intermittently provided in the N surface of the wafer 10 along the scribe line L10 set between the adjacent semiconductor laser elements 100 in the N surface of the wafer 10.

The groove shape of each of the N surface scribes 106 is, for example, a cone or an elliptic cone having a minor axis or a major axis corresponding to the scanning direction of laser light in laser ablation processing, as described above.

The length of the N surface scribe 106 in the element width direction may be set to range, for example, from approximately 2.0 to 20 μm, and can be, for example, 8 μm. Further, the length of the N surface scribe 106 in the resonator length direction may be set to range, for example, from approximately 2.0 to 10 μm, and can be, for example, 2 μm. Note that the length of the N surface scribe 106 in the element width direction is longer than the distance between the adjacent N surface scribes 106.

The depth of the N surface scribe 106, that is, the length, from the N surface, of a groove-like machining trace 105 corresponding to the machining trace of the N surface scribe 106 formed in the resonator end surface 102 or 103 (hereinafter referred to as the depth of the N surface scribe 106) in the substrate thickness direction, may be, for example, sufficient to avoid reaching the light emission layer 14 in the epitaxial layer 2 as depicted in FIG. 14, and can be, for example, approximately 35 μm. However, to exert the effect of formation of the N surface scribes 106 to some degree, the depth of the N surface scribe 106 is preferably set to, for example, one-third or more of the length from the N surface to the P surface.

Note that, in a case where the length of the N surface scribe 106 in the element width direction is used as a reference, the depth of the N surface scribe 106 may be a length approximately five to ten times as long as the length of the N surface scribe 106 in the element width direction. Further, in a case where the film thickness of the epitaxial layer 2 is, for example, approximately 10 μm, the depth of the N surface scribe 106 may be sufficient to avoid reaching the light emission layer 14 from the N surface, that is, approximately 10 μm.

The pitch of the N surface scribes 106 arranged along the scribe line L10 may be set to, for example, approximately 2 to 30 μm and can be, for example, approximately 20 μm. In that case, by making the length, in the element width direction, of the region in which the N surface scribes 106 are formed longer than the length, in the element width direction, of the region in which no N surface scribes 106 are formed, the effect of formation of the N surface scribes 106 can be fully exerted. For example, in a case where the length, in the element width direction, of the region in which the N surface scribes 106 are formed (the length of the N surface scribe 106 in the element width direction) is 8 μm, the effect of formation of the N surface scribes 106 can be fully produced by setting the length, in the element width direction, of the region in which no N surface scribes 106 are formed to 2 μm corresponding to a length sufficiently shorter than the length of the N surface scribe 106 in the element width direction.

Note that the pitch may be a distance from the opening center of the N surface scribe 106 in the N surface to the opening center of the adjacent N surface scribe 106.

Further, the adjacent N surface scribes 106 need not necessarily be separated from each other. In other words, the configuration in which the region in which no N surface scribes 106 are formed is interposed between the adjacent N surface scribes 106 that are spaced apart from each other is not essential, and the adjacent N surface scribes 106 may partially overlap near the N surface. However, even in that case, at the tip of the N surface scribe 106 (position farthest from the N surface), the adjacent N surface scribes 106 are preferably separated from each other.

By cleaving the wafer 10 with the N surface scribes 106 as described above being formed in the N surface of the wafer 10, the second moment of area of the cleavage portion can be increased, as depicted in FIG. 15. Accordingly, compared to, for example, a configuration in which a continuous guide groove 906 is formed in the N surface of the wafer 900 as depicted in FIG. 16, the wafer 10 can suppress development of cracking from the N surface side along an unintended surface. Note that, in FIG. 15 an FIG. 16, (a) is a diagram depicting a general cross section of the wafer 10/910 along the scribe line, and (b) is a diagram depicting the direction of force during cleavage applied to the wafer 10/910.

Further, a region in which no guide grooves are formed may be provided in a part of the N surface resulting from segmentation of a continuous linear guide groove formed in the N surface (see, for example, FIG. 16). However, in this case, development of unintended cracking from the N surface side can be reduced, but obtaining a sufficient depth is difficult. Consequently, the effect of forming perpendicular resonator end surfaces is not as sufficient as the effect produced by the N surface scribes 106 according to the present embodiment.

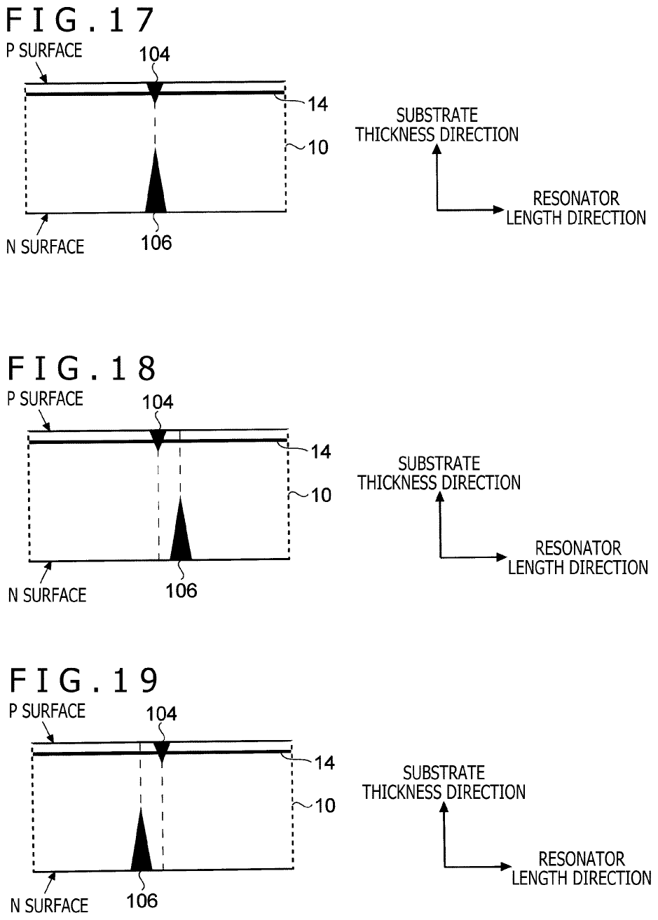

Note that, as depicted in FIG. 17, the position on the N surface at which each N surface scribe 106 is formed desirably corresponds, in the resonator length direction, to the position on the P surface at which the corresponding P surface guide groove 104 is formed but one of the positions may be displaced leftward or rightward from the other along the resonator length direction, for example, as depicted in FIG. 18 or FIG. 19.

### 1.7 Operations and Effects

As described above, in the present embodiment, the N surface scribes 106 are intermittently formed in the N surface at short intervals. By formation of the N surface scribes 106 intermittently repeated at short intervals, unintended development of cracking from the N surface side can be suppressed, enabling deeper scribes to be formed. As a result, the perpendicularity of the resonator end surfaces 102 and 103 can be improved to suppress degradation of the laser characteristics.

Moreover, by intermittently forming the N surface scribes 106 at short intervals, the region in which no scribes are present between N surface scribes 106 can be made very short, thus enabling stress during cleavage to concentrate near the light emission layer 14. Accordingly, development of cracking in the element width direction can be suppressed to reduce a fault near the light emission layer 14.

Further, unintended development of cracking from the N surface side is suppressed, enabling much deeper N surface scribes 106 to be formed. This allows the perpendicularity of the resonator end surfaces 102 and 103 to be more stably improved. As a result, not only can the laser characteristics be improved, but also variations in laser characteristics can be suppressed. Specifically, for example, threshold current and slope efficiency can be improved, and variations in threshold current and slope efficiency can be suppressed. Further, misalignment of the optical axis in an FFP (Far-Field Pattern) spectrum and a variation in misalignment can be suppressed.

Furthermore, the improved flatness of the resonator end surfaces 102 and 103 enables improvement of an ESD (Electro Static Discharge) level, a COD (Catastrophic Optical Damage) level, and long-term reliability.

### 2. Second Embodiment

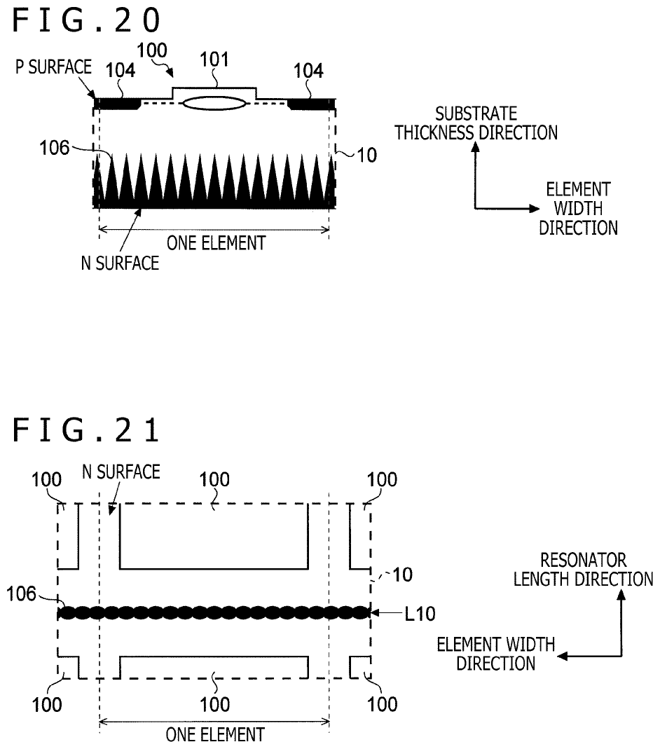

In the first embodiment described above, illustrated is the case in which, in principle, the region in which no N surface scribes 106 are formed is interposed between the adjacent N surface scribes 106. However, the present disclosure is not limited to such a configuration, and the adjacent N surface scribes 106 may overlap near the N surface, for example, as depicted in FIG. 20 and FIG. 21. Note that FIG. 20 is a diagram depicting a part of a cross section structure example of a wafer that is provided with semiconductor laser elements according to the second embodiment and that has been cut along a scribe line and that FIG. 21 is a diagram depicting a part of a configuration example of the wafer provided with the semiconductor laser elements according to the second embodiment as viewed from the N surface side.

The configuration as described also includes the N surface scribes 106 formed in the N surface at short intervals, thus enabling suppression of unintended development of cracking from the N surface side as is the case with the first embodiment. As a result, the perpendicularity of the resonator end surfaces 102 and 103 can be improved to suppress degradation of the laser characteristics.

The other configurations, manufacturing methods, and effects may be similar to the corresponding configurations, manufacturing methods, and effects of the embodiment described above, and thus detailed descriptions thereof are omitted here.

### 3. Third Embodiment

Further, in the embodiment described above, illustrated is the case in which the N surface scribe 106 is conical or elliptic conical. However, the present disclosure is not limited to such a configuration.

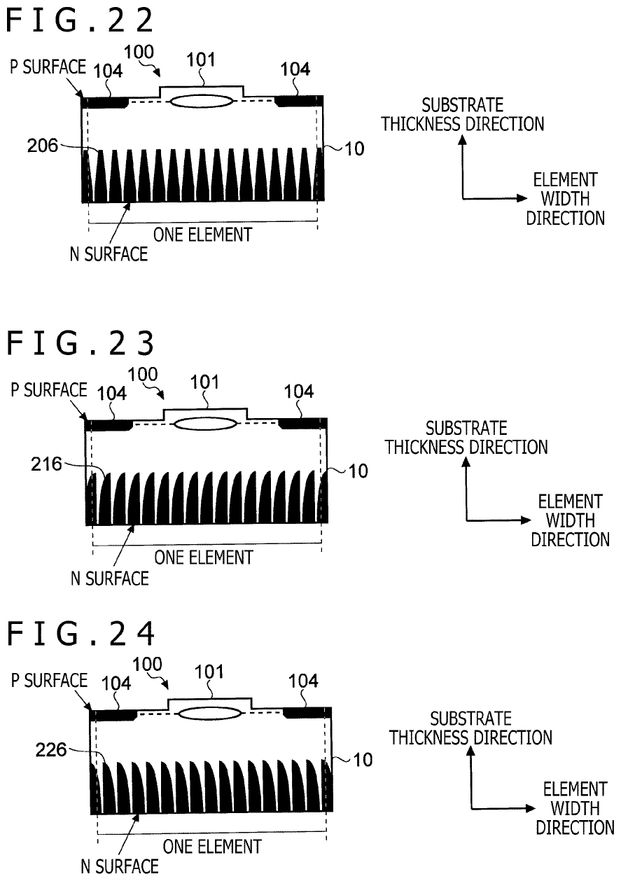

For example, in a case where the N surface is designated as a bottom surface, the top portion may be a flat surface as in N surface scribes 206 illustrated in FIG. 22.

Alternatively, the top portion may have an obtuse angle or a curved surface instead of the flat surface. Further, the vicinity of the N surface may be cylindrical as in the N surface scribes 206 illustrated in FIG. 22.

In addition, in a case where the N surface is designated as a bottom surface, the top portion may be shifted from the center of the opening in the N surface in the element width direction as in N surface scribes 216 illustrated in FIG. 23 or N surface scribes 226 illustrated in FIG. 24, for example. In that case, as depicted in FIG. 23 or FIG. 24, grooves (corresponding to the groove-like machining traces 105 in the first embodiment) appearing when a wafer on which semiconductor laser elements are formed is cleaved may each have, at the cleavage surface, a shape in which one of the oblique sides is a generally straight line, whereas the other oblique side is a curve.

As described above, the N surface scribes formed in the wafer can be varied as long as the N surface scribes are shaped to have a thin top portion in a case of being viewed in the element width direction.

Further, the configuration as described also includes the N surface scribes 106 formed in the N surface at short intervals, thus enabling suppression of unintended development of cracking from the N surface side as is the case with the embodiments described above. As a result, the perpendicularity of the resonator end surfaces 102 and 103 can be improved to suppress degradation of the laser characteristics.

The other configurations, manufacturing methods, and effects may be similar to the corresponding configurations, manufacturing methods, and effects of the embodiments described above, and thus detailed descriptions thereof are omitted here.

### 4. Fourth Embodiment

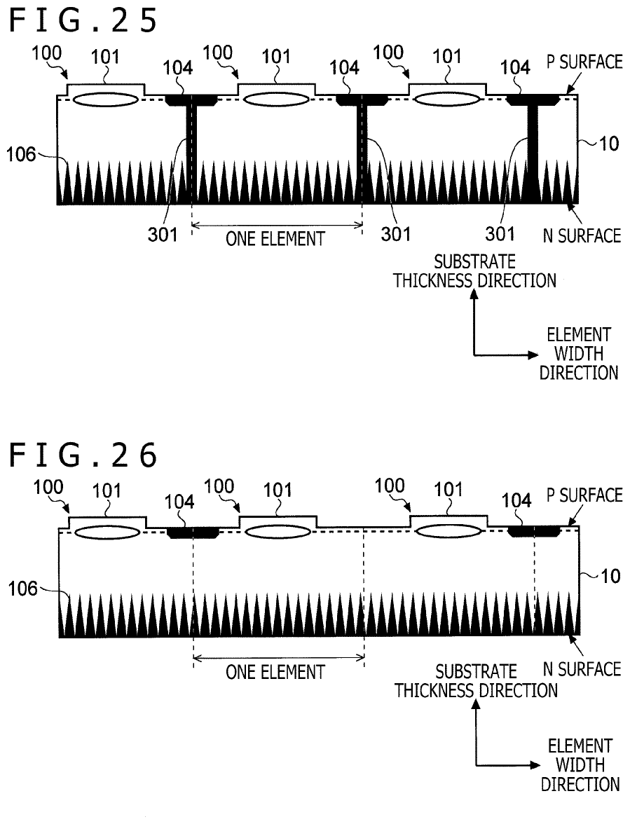

Further, as illustrated in FIG. 25, in addition to the P surface guide grooves 104 and the N surface scribes 106 (including the N surface scribes 206 and 216; the same applies to the description below), through-holes 301 may be formed to penetrate, in the substrate thickness direction, the wafer 10 on which the semiconductor laser elements 100 are formed. Each of the through-holes 301 may be formed, for example, in a partial region including at least one corner of each of the semiconductor laser elements 100 on the wafer 10.

When the semiconductor laser element 100 are obtained from singulation, each through-hole 301 remains as a groove that is located in the corner of the semiconductor laser element 100 and that extends from the P surface to the N surface.

When the through-holes 301 are each provided in the partial region including at least one corner of each of the semiconductor laser elements 100 as described above, development of cracking from the corner can be reduced. Accordingly, the perpendicularity of the resonator end surfaces 102 and 103 can be improved to suppress degradation of the laser characteristics.

The other configurations, manufacturing methods, and effects may be similar to the corresponding configurations, manufacturing methods, and effects of the embodiments described above, and thus detailed descriptions thereof are omitted here.

### 5. Fifth Embodiment

Further, the P surface guide groove 104 need not be provided in the corners of all the semiconductor laser elements 100 on the P surface of the wafer 10. For example, as illustrated in FIG. 26, the semiconductor laser element 100 can be configured such that the P surface guide groove 104 is not provided in at least one of the corners of the semiconductor laser element 100.

Such a configuration can also suppress unintended development of cracking from the N surface side as is the case with the embodiments described above. As a result, the perpendicularity of the resonator end surfaces 102 and 103 can be improved to suppress degradation of the laser characteristics.

The other configurations, manufacturing methods, and effects may be similar to the corresponding configurations, manufacturing methods, and effects of the embodiments described above, and thus detailed descriptions thereof are omitted here.

### 6. Sixth Embodiment

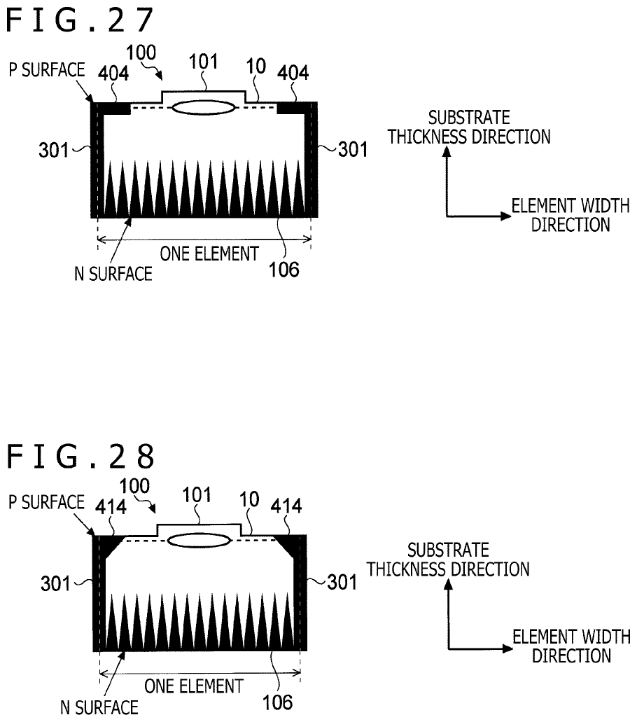

Further, in the embodiments described above, illustrated is the case in which the groove shape of the P surface guide groove 104 as viewed in the resonator length direction is a general trapezoid. However, the present disclosure is not limited to such a configuration, and for example, the shape as viewed in the resonator length direction may be a general rectangle as in P surface guide grooves 404 illustrated in FIG. 27, or the shape as viewed in the resonator length direction may be a general triangle as in P surface guide grooves 414 illustrated in FIG. 28.

AS described above, the groove shape of the P surface guide groove 104 as viewed in the resonator length direction can be varied.

Further, the configuration as described above also includes the N surface scribes 106 formed in the N surface at short intervals, thus enabling suppression of unintended development of cracking from the N surface side as is the case with the embodiments described above. As a result, the perpendicularity of the resonator end surfaces 102 and 103 can be improved to suppress degradation of the laser characteristics.

The other configurations, manufacturing methods, and effects may be similar to the corresponding configurations, manufacturing methods, and effects of the embodiments described above, and thus detailed descriptions thereof are omitted here.

### 7. Seventh Embodiment

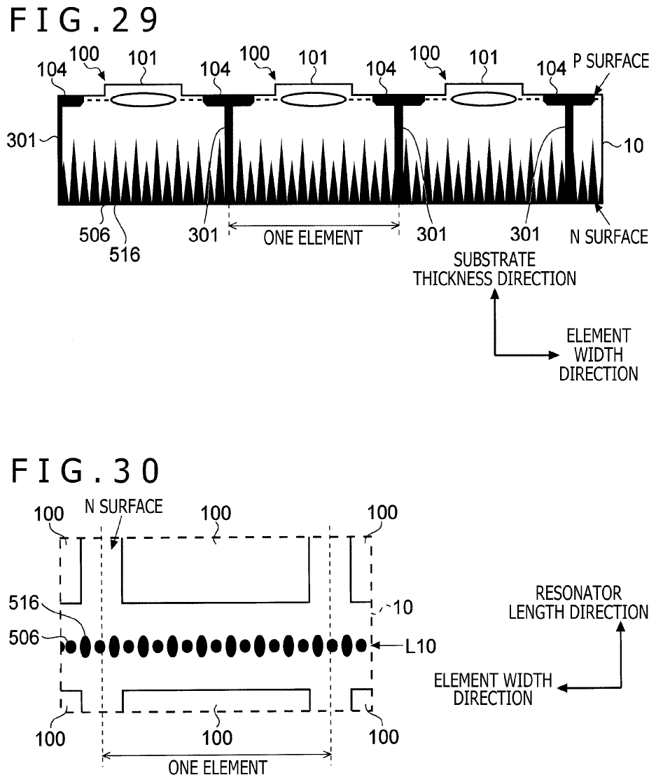

Further, in the first embodiment described above, illustrated is the case in which the N surface scribes 106 have a substantially constant depth, but the present disclosure is not limited to such a configuration. For example, as illustrated in FIG. 29, a configuration in which N surface scribes 506 and 516 having different depths are alternately arranged along the scribe line can also be provided.

The N surface scribes 506 and 516 having different depths can be formed by, for example, changing the intensity distribution, in the resonator length direction, of the laser pulse used for the laser ablation processing. In that case, as depicted in FIG. 30, the opening of each of the deeper N surface scribes 516 in the N surface of the wafer 10 may be longer in the resonator length direction than the opening of each of the shallower N surface scribes 506 in the N surface of the wafer 10.

However, formation of the N surface scribes 506 and 516 having different depth is not limited to the formation based on the intensity distribution of the laser pulse in the resonator length direction, and the N surface scribes 506 and 516 having different depths may be locked by changing the intensity distribution in the element width direction. In that case, the opening of each of the deeper N surface scribes 516 in the N surface of the wafer 10 may be longer in the resonator length direction than the opening of each of the shallower N surface scribes 506 in the N surface of the wafer 10.

Such a configuration also includes the N surface scribes 506 and 516 formed in the N surface at short intervals, thus enabling suppression of unintended development of cracking from the N surface side as is the case with the embodiments described above. As a result, the perpendicularity of the resonator end surfaces 102 and 103 can be improved to suppress degradation of the laser characteristics.

The other configurations, manufacturing methods, and effects may be similar to the corresponding configurations, manufacturing methods, and effects of the embodiments described above, and thus detailed descriptions thereof are omitted here.

### 8. Eighth Embodiment

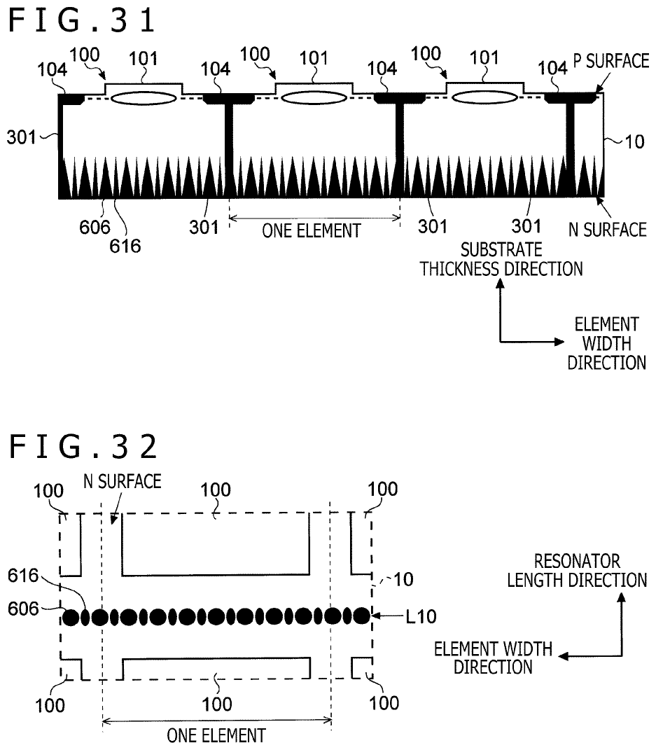

Further, in the first embodiment described above, illustrated is the case in which the N surface scribes 106 have a constant length in the element width direction, but the present disclosure is not limited to such a configuration. For example, as depicted in FIG. 31, a configuration in which N surface scribes 606 and 616 having different lengths in the element width direction are alternately arranged along the scribe line can be provided.

The N surface scribes 606 and 616 having different lengths in the element width direction can be formed by changing the intensity distribution, in the element width direction, of the laser pulse used for the laser ablation processing or changing the pulse length of the laser pulse, for example. In that case, as depicted in FIG. 32, the opening of each of the longer N surface scribes 516 in the N surface of the wafer 10 may be longer in the element width direction than the opening of each of the shorter N surface scribes 506 in the N surface of the wafer 10.

Such a configuration also includes the N surface scribes 606 and 616 formed in the N surface at short intervals, thus enabling suppression of unintended development of cracking from the N surface side as is the case with the embodiments described above. As a result, the perpendicularity of the resonator end surfaces 102 and 103 can be improved to suppress degradation of the laser characteristics.

The other configurations, manufacturing methods, and effects may be similar to the corresponding configurations, manufacturing methods, and effects of the embodiments described above, and thus detailed descriptions thereof are omitted here.

### 9. Ninth Embodiment

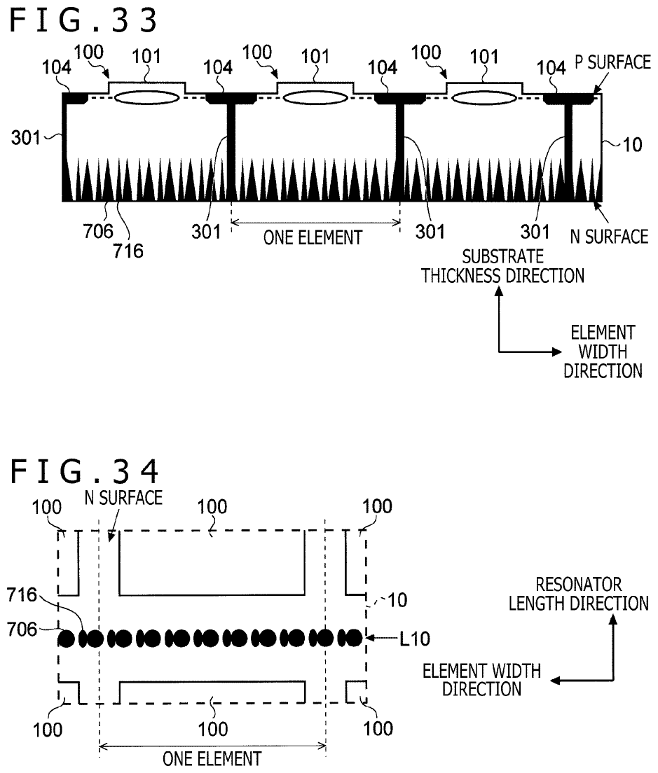

Further, in the first embodiment described above, illustrated is the case in which the N surface scribes 106 are arranged at a constant pitch, but the present disclosure is not limited to such a configuration. For example, as depicted in FIG. 33, N surface scribes 706 and 716 alternately arranged along the scribe line can be formed by alternately switching between pitches with different lengths.

In that case, as depicted in FIG. 33 and FIG. 34, one of the N surface scribe 706 and the N surface scribe 716 (in FIG. 33 and FIG. 34, the N surface scribe 706) may be longer in the element width direction than the other (in FIG. 33 and FIG. 34, the N surface scribe 716).

Such a configuration also includes the N surface scribes 706 and 716 formed in the N surface at short intervals, thus enabling suppression of unintended development of cracking from the N surface side as is the case with the embodiments described above. As a result, the perpendicularity of the resonator end surfaces 102 and 103 can be improved to suppress degradation of the laser characteristics.

The other configurations, manufacturing methods, and effects may be similar to the corresponding configurations, manufacturing methods, and effects of the embodiments described above, and thus detailed descriptions thereof are omitted here.

The embodiments of the present disclosure have been described above. However, the technical scope of the present disclosure is not limited directly to the above-described embodiments, and various changes may be made to the embodiments without departing from the spirit of the present disclosure. Further, components of different embodiments and variations may be combined together as appropriate.

In addition, the effects of the embodiments described herein are only illustrative and not restrictive, and other effects may be produced.

Note that the present technique can also take the following configurations.

(1)

A semiconductor apparatus including:

a semiconductor chip including a semiconductor substrate including a group-III nitride semiconductor and a laminate structure located on a first surface of the semiconductor substrate,

in which, on at least one of side surfaces of the semiconductor chip orthogonal to the first surface, plural groove-like machining traces are provided at a pitch of 2 μm (micrometers) or more but 20 μm or less in a direction parallel to a second surface of the semiconductor substrate opposite to the first surface of the semiconductor substrate, the groove-like machining traces extending from the second surface to a third surface of the laminate structure opposite to a surface of the laminate structure contacting the first surface.

(2)

The semiconductor apparatus according to (1) described above, in which the plural groove-like machining traces have a length that is one-third or more of a length from the second surface to the third surface.

(3)

The semiconductor apparatus according to (1) or (2) described above, in which the plural groove-like machining traces are provided intermittently, and

a length of each of the groove-like machining traces on the second surface in a direction parallel to the second surface is longer than a length between the groove-like machining traces adjacent to each other.

(4)

The semiconductor apparatus according to any one of (1) to (3) described above, in which the length of each of the groove-like machining traces on the second surface in the direction parallel to the second surface is 10 μm or less, and

the length of each of the groove-like machining traces on the second surface in a direction perpendicular to the direction parallel to the second surface is 2 μm or more.

(5)

The semiconductor apparatus according to any one of (1) to (4) described above, in which a shape of each of the groove-like machining traces on the second surface is a semicircle or a semi-ellipse.

(6)

The semiconductor apparatus according to any one of (1) to (5) described above, in which, when the second surface side of each of the groove-like machining traces is designated as a bottom side, a top of the groove-like machining trace has an angle of 30° or less.

(7)

The semiconductor apparatus according to any one of (1) to (6) described above, in which the length of each of the groove-like machining traces on the second surface in the direction parallel to the second surface ranges from ⅕ to 1/10 of the length of each of the groove-like machining traces from the second surface toward the third surface.

(8)

The semiconductor apparatus according to any one of (1) to (7) described above, in which the plural groove-like machining traces include two groove-like machining traces differing in length from the second surface toward the third surface.

(9)

The semiconductor apparatus according to any one of (1) to (8) described above, in which the plural groove-like machining traces include at least two groove-like machining traces differing in length on the second surface in the direction parallel to the second surface.

(10)

The semiconductor apparatus according to any one of (1) to (9) described above, in which the pitch includes at least two pitches differing in length.

(11)

The semiconductor apparatus according to any one of (1) to (10) described above, in which the at least one side surface is provided with an inclined surface portion extending from the third surface toward the second surface.

(12)

The semiconductor apparatus according to any one of (1) to (11) described above, in which at least one corner of the semiconductor chip is provided with a groove extending from the third surface to the second surface.

(13)

The semiconductor apparatus according to any one of (1) to (12) described above, in which the first surface is a semi-polar surface.

(14)

The semiconductor apparatus according to any one of (1) to (13) described above, in which the third surface has a first conductivity type, and

the second surface has a second conductivity type opposite to the first conductivity type.

(15)

The semiconductor apparatus according to (14) described above, in which the first conductivity type is a p type, and

the second conductivity type is an n type.

(16)

The semiconductor apparatus according to any one of (1) to (15) described above, in which the laminate structure includes an epitaxial layer.

(17)

The semiconductor apparatus according to any one of (1) to (16) described above, in which the laminate structure includes a light emission layer, and

the plural groove-like machining traces are formed in a part of a portion from the second surface to the light emission layer.

(18)

The semiconductor apparatus according to any one of (1) to (17) described above, in which the laminate structure includes a ridge structure on the third surface.

(19)

The semiconductor apparatus according to any one of (1) to (18) described above, in which the semiconductor apparatus includes a semiconductor laser.

(20)

A method for manufacturing a semiconductor apparatus, the method including the steps of:

producing a semiconductor chip including a laminate structure on a first surface of a semiconductor substrate including a group-III nitride semiconductor;

forming plural semiconductor elements to be arranged on the semiconductor chip in a two-dimensional grid pattern;

forming plural scribes between the semiconductor elements adjacent to each other on the semiconductor chip, at a pitch of 2 μm or more but 20 μm or less, the scribes extending from a second surface opposite to the first surface toward a third surface of the laminate structure opposite to a surface of the laminate structure contacting the first surface; and

cleaving the semiconductor chip in which the plural scribes are formed, by pressing the semiconductor chip from the first surface side.

### REFERENCE SIGNS LIST

1: Semiconductor substrate
1a: Semi-polar surface
1b: Back surface
2: Epitaxial layer
3: Insulating layer
4: First electrode
5: Second electrode
11: Buffer layer
12: First clad layer
13: First light guide layer
14: Light emission layer
15: Second light guide layer
16: Carrier block layer
17: Second clad layer
17a: Ridge portion
18: Contact layer
100: Semiconductor laser element
101: Stripe portion
102, 103: Resonator end surface
104, 404, 414: P surface guide groove
104a to 104d: Inclined surface portion
105: Groove-like machining trace
106, 206, 216, 226, 506, 516, 606, 616, 706, 716: N surface scribe
301: Through-hole
L10: Scribe line

1. A semiconductor apparatus comprising:
a semiconductor chip including a semiconductor substrate including a group-III nitride semiconductor and a laminate structure located on a first surface of the semiconductor substrate,
wherein, on at least one of side surfaces of the semiconductor chip orthogonal to the first surface, plural groove-like machining traces are provided at a pitch of 2 μm (micrometers) or more but 30 μm or less in a direction parallel to a second surface of the semiconductor substrate opposite to the first surface of the semiconductor substrate, the groove-like machining traces extending from the second surface to a third surface of the laminate structure opposite to a surface of the laminate structure contacting the first surface.

2. The semiconductor apparatus according to claim 1, wherein the plural groove-like machining traces have a length that is one-third or more of a length from the second surface to the third surface.

3. The semiconductor apparatus according to claim 1, wherein the plural groove-like machining traces are provided intermittently, and
a length of each of the groove-like machining traces on the second surface in a direction parallel to the second surface is longer than a length between the groove-like machining traces adjacent to each other.

4. The semiconductor apparatus according to claim 1, wherein a length of each of the groove-like machining traces on the second surface in the direction parallel to the second surface is 10 μm or less, and
a length of each of the groove-like machining traces on the second surface in a direction perpendicular to the direction parallel to the second surface is 2 μm or more.

5. The semiconductor apparatus according to claim 1, wherein a shape of each of the groove-like machining traces on the second surface is a semicircle or a semi-ellipse.

6. The semiconductor apparatus according to claim 1, wherein, when the second surface side of each of the groove-like machining traces is designated as a bottom side, a top of the groove-like machining trace has an angle of 30° or less.

7. The semiconductor apparatus according to claim 1, wherein a length of each of the groove-like machining traces on the second surface in the direction parallel to the second surface ranges from ⅕ to 1/10 of a length of each of the groove-like machining traces from the second surface toward the third surface.

8. The semiconductor apparatus according to claim 1, wherein the plural groove-like machining traces include two groove-like machining traces differing in length from the second surface toward the third surface.

9. The semiconductor apparatus according to claim 1, wherein the plural groove-like machining traces include at least two groove-like machining traces differing in length on the second surface in the direction parallel to the second surface.

10. The semiconductor apparatus according to claim 1, wherein the pitch includes at least two pitches differing in length.

11. The semiconductor apparatus according to claim 1, wherein the at least one side surface is provided with an inclined surface portion extending from the third surface toward the second surface.

12. The semiconductor apparatus according to claim 1, wherein at least one corner of the semiconductor chip is provided with a groove extending from the third surface to the second surface.

13. The semiconductor apparatus according to claim 1, wherein the first surface is a semi-polar surface.

14. The semiconductor apparatus according to claim 1, wherein the third surface has a first conductivity type, and
the second surface has a second conductivity type opposite to the first conductivity type.

15. The semiconductor apparatus according to claim 14, wherein the first conductivity type is a p type, and
the second conductivity type is an n type.

16. The semiconductor apparatus according to claim 1, wherein the laminate structure includes an epitaxial layer.

17. The semiconductor apparatus according to claim 1, wherein the laminate structure includes a light emission layer, and
the plural groove-like machining traces are formed in a part of a portion from the second surface to the light emission layer.

18. The semiconductor apparatus according to claim 1, wherein the laminate structure includes a ridge structure on the third surface.

19. The semiconductor apparatus according to claim 1, wherein the semiconductor apparatus includes a semiconductor laser.

20. A method for manufacturing a semiconductor apparatus, the method comprising the steps of:
producing a semiconductor chip including a laminate structure on a first surface of a semiconductor substrate including a group-III nitride semiconductor;
forming plural semiconductor elements to be arranged on the semiconductor chip in a two-dimensional grid pattern;
forming plural scribes between the semiconductor elements adjacent to each other on the semiconductor chip, at a pitch of 2 μm or more but 20 μm or less, the scribes extending from a second surface opposite to the first surface toward a third surface of the laminate structure opposite to a surface of the laminate structure contacting the first surface; and
cleaving the semiconductor chip in which the plural scribes are formed, by pressing the semiconductor chip from the first surface side.
